(19) United States
(12) Patent Application Publication
(10) Pub. No.: US 2025/0254786 A1
(43) Pub. Date: Aug. 7, 2025

(54) ELECTRONIC DEVICE

(71) Applicant: DENSO CORPORATION, Kariya-city (JP)

(72) Inventors: YUICHIRO SASAKI, Kariya-city (JP); HIROYOSHI KUNIEDA, Kariya-city (JP)

(21) Appl. No.: 19/039,954

(22) Filed: Jan. 29, 2025

(30) Foreign Application Priority Data
Feb. 6, 2024 (JP) 2024-016517

(51) Int. Cl. H05K 1/02; H05K 1/18

(52) U.S. Cl. CPC H05K 1/0203; H05K 1/181; H05K 2201/10409; H05K 2201/10734

(57) ABSTRACT

An electronic device includes a printed circuit board, an electronic component disposed on a first surface of the printed circuit board, a cooler facing the first surface, a heat conductive member interposed between the electronic component and the cooler, and a back plate disposed on a second surface of the printed circuit board. A main body portion of the back plate is disposed to overlap with at least a part of the electronic component in a plan view and in contact with the second surface. Leg portions of the back plate extend from the main body portion, and are spaced apart from the second surface of the printed circuit board. A fixing part for fixing at least one of the leg portions of the back plate and the cooler passes through a through hole of the printed circuit board, and is not in contact with the printed circuit board.

### CROSS REFERENCE TO RELATED APPLICATION

The present application claims the benefit of priority from Japanese Patent Application No. 2024-016517 filed on Feb. 6, 2024. The entire disclosures of the above application are incorporated herein by reference.

### TECHNICAL FIELD

The present disclosure relates to an electronic device.

### BACKGROUND

WO2022/192031A1 describes an electronic device having a cooler, a printed circuit board, an electronic component, a heat conductive member, and a back plate. Description of WO2022/192031A1 is incorporated herein by reference as description of technical elements of the present disclosure.

### SUMMARY

The present disclosure described an electronic device. According to an aspect, an electronic device includes a printed circuit board, an electronic component disposed on a first surface of the printed circuit board, a cooler disposed to face the first surface of the printed circuit board, a heat conductive member interposed between the electronic component and the cooler, and a back plate disposed on a second surface of the printed circuit board. The back plate has a main body portion and a plurality of leg portions. The main body portion of the back plate is disposed to overlap with at least a part of the electronic component in a plan view and in contact with the second surface of the printed circuit board. The leg portions of the back plate extend from the main body portion, and are spaced apart from the second surface of the printed circuit board. A fixing part for fixing at least one of the leg portions of the back plate and the cooler passes through a through hole of the printed circuit board, and is not in contact with the printed circuit board.

### BRIEF DESCRIPTION OF DRAWINGS

Objects, features and advantages of the present disclosure will become more apparent from the following detailed description made with reference to the accompanying drawings, in which like parts are designated by like reference numbers and in which:

FIG. 1 is a cross-sectional view showing an electronic device according to a first embodiment;

FIG. 2 is a plan view when viewed along a Z1 direction shown in FIG. 1;

FIG. 3 is a cross-sectional view showing a reference example;

FIG. 4 is a cross-sectional view showing a reference example;

FIG. 5 is a cross-sectional view showing a modified example;

FIG. 6 is a cross-sectional view showing a modified example;

FIG. 7 is a cross-sectional view showing a modified example;

FIG. 8 is a cross-sectional view showing a modified example;

FIG. 9 is a cross-sectional view showing an electronic device according to a second embodiment;

FIG. 10 is a plan view when viewed along a Z1 direction shown in FIG. 1;

FIG. 11 is a plan view showing an electronic device according to a third embodiment;

FIG. 12 is a plan view showing an electronic device according to a fourth embodiment; and

FIG. 13 is a plan view showing an electronic device according to a fifth embodiment.

### DETAILED DESCRIPTION

In an electronic device of WO2022/192031A1, a heat conductive member is interposed between a cooler and an electronic component disposed on one surface of a printed circuit board. In addition, a back plate is disposed on a back surface of the printed circuit board. According to this configuration, a load is applied to the printed circuit board from the back surface side by the back plate to compress the heat conductive member, so that a thermal resistance can be thus reduced. However, since the back plate is fixed to the cooler via the printed circuit board, distortion is likely to occur around a fixing portion in the printed circuit board, which decreases the connection reliability of the electronic component. In the viewpoint described above, or in another viewpoint not mentioned, such an electronic device is required to be further improved.

The present disclosure provides an electronic device capable of suppressing a degradation in connection reliability while reducing a thermal resistance.

According to an aspect of the present disclosure, an electronic device includes a printed circuit board, an electronic component, a cooler, a heat conductive member, and a back plate. The printed circuit board has a first surface, and a second surface opposite to the first surface in a thickness direction. The printed circuit board is formed with a through hole defining openings on the first surface and the second surface. The electronic component is disposed on the first surface of the printed circuit board at a position without overlapping with the through hole in a plan view when viewed in the thickness direction. The cooler is disposed to face the first surface of the printed circuit board. The heat conductive member is interposed between the electronic component and the cooler and thermally connects the electronic component and the cooler. The back plate is disposed on the second surface of the printed circuit board and fixed to the cooler via the through hole. The back plate has a main body portion and a plurality of leg portions. The main body portion is disposed so as to overlap with at least a part of the electronic component in the plan view and in contact with the second surface of the printed circuit board. The plurality of leg portions extends from the main body portion and is spaced apart from the second surface of the printed circuit board. A fixing part for fixing at least one of the leg portions of the back plate and the cooler passes through the through hole and is not in contact with the printed circuit board.

According to the electronic device described above, the main body portion of the back plate is in contact with the second surface of the printed circuit board at a position overlapping with at least a portion of the electronic component. Therefore, the heat conductive member can be compressed and the thermal resistance can be reduced. In addition, the leg portions of the back plate are disposed to be spaced apart from the second surface of the printed circuit board, and the fixing part passes through the through hole without being in contact with the printed circuit board. As a result, a mounting portion of the electronic component will not be affected by a stress caused by the fixing of the leg portion and the cooler. Therefore, it is possible to suppress the degradation of connection reliability while reducing the thermal resistance.

Hereinafter, multiple embodiments will be described with reference to the drawings. The same or corresponding elements are denoted by the same reference numerals throughout the embodiments, and descriptions thereof will not be repeated. When only part of the configurations is described in each embodiment, the configurations of the other preceding embodiments can be applied to other parts of the configurations. Further, not only the combinations of the configurations explicitly shown in the description of the respective embodiments, but also the configurations of the multiple embodiments can be partially combined even when they are not explicitly shown as long as there is no difficulty in the combination in particular.

### First Embodiment

First, a schematic configuration of an electronic device will be described. The electronic device is also referred to as an electronic control unit (ECU). For example, the electronic device may be mounted on a mobile object. Examples of the mobile object include a vehicle, a flying object, a ship, a construction machine, and an agricultural machine. The electronic device of the present embodiment is mounted on a vehicle, for example.

### <Electronic Device>

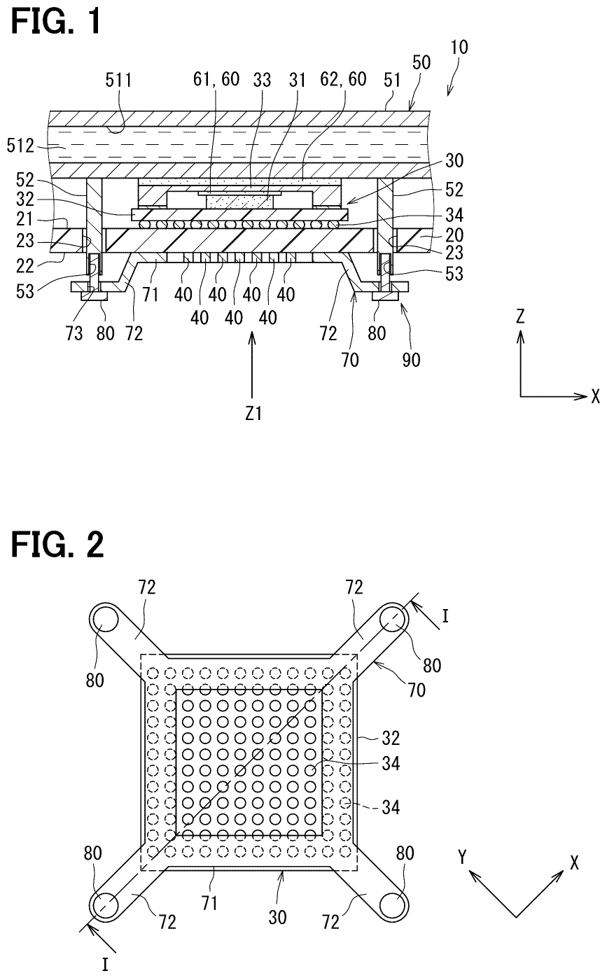

FIG. 1 is a cross-sectional view showing an example of the electronic device. FIG. 1 shows a part of the electronic device, in particular, a periphery of an electronic component around which a heat conductive member is interposed between the electronic component and a cooler. FIG. 1 is a cross-sectional view taken along a line I-I in FIG. 2. FIG. 2 is a plan view when viewed along a Z1 direction shown in FIG. 1. FIG. 2 shows the shapes of the electronic component and a back plate, as well as the positional relationship between the electronic component and the back plate. In FIG. 2, illustrations of a printed circuit board and an electronic component on the back side are omitted.

In the following, a thickness direction of the printed circuit board is referred to as a Z direction. Further, a direction perpendicular to the Z direction is referred to as an X direction, and a direction perpendicular to both of the Z direction and the X direction is referred to as a Y direction. Unless otherwise specified, a shape viewed along the Z direction, that is, a shape along an XY plane defined by the X direction and Y direction is referred to as a planar shape. A plan view when viewed along the Z direction may be simply referred to as the plan view.

As shown in FIGS. 1 and 2, an electronic device 10 includes a printed circuit board 20, electronic components 30 and 40, a cooler 50, a TIM 60, a back plate 70, and screws 80. The printed circuit board 20 is also referred to as a substrate, a wiring board, a printed wiring board, or the like. The printed circuit board 20 has a first surface 21 and a second surface 22. The second surface 22 is a back surface, and is opposite to the first surface 21 in the Z direction, which is the thickness direction of the printed circuit board 20. The printed circuit board 20 has a planar shape that is not particularly limited. As an example, the printed circuit board 20 of the present embodiment has a substantially rectangular planar shape. The printed circuit board 20 is fixed to a housing. The printed circuit board 20 may be fixed to the cooler 50 that forms a part of the housing.

The printed circuit board 20 has an insulating base material and a conductor. The insulating base material is made of a material having an electrical insulation property, such as a resin. As the insulating base material, a material containing only a resin may be used, or a material in which a glass fabric, a nonwoven fabric, or the like is combined with a resin may be used, for example. The conductor is made of a metal material having a favorable conductivity such as copper (Cu). The conductor includes a wiring. The wiring will be also referred to as a wiring layer, a wiring pattern, a conductor pattern, or the like.

The wiring may be formed by patterning a metal foil, or may be formed by printing, for example. At least a part of the conductor forms a circuit together with the electronic component mounted on the printed circuit board 20. For this reason, the printed circuit board 20 on which the electronic component is mounted is also referred to as a circuit board.

The wiring includes at least a surface wiring disposed in a surface layer on the first surface 21 side of the insulating base material. The wiring may include a surface wiring disposed in a surface layer on the second surface 22 side, or may include an inner layer wiring disposed inside the insulating base material. That is, the printed circuit board 20 may be a single-layer board, a double-sided board, or a multi-layer board. As an example, the printed circuit board 20 of the present embodiment is a multi-layer board including an inner layer wiring. The printed circuit board 20 has lands (not shown) in the surface layers on the first surface 21 and the second surface 22, and the lands serve as electrode portions of wirings.

The conductor may include a via conductor or a through hole land, in addition to the wiring. The via conductor is formed by arranging a conductor such as a plating in a through hole (via) formed in an insulating layer of the insulating base material. The via conductor electrically connects wirings disposed in different layers to each other, for example. The through hole land is formed on a wall surface of a through hole that penetrates the printed circuit board 20 in the Z direction. The conductor may include a conductor that does not provide a circuit function (wiring function), such as a conductor for heat dissipation.

The printed circuit board 20 has a through hole 23. The through hole 23 penetrates the printed circuit board 20. The through hole 23 extends in the Z direction and defines an opening on the first surface 21 and an opening on the second surface 22. The through hole 23 is a hole for fixing the back plate 70 to the cooler 50. The through hole 23 has a diameter that is larger than an outer diameter of a screw receiving portion 52 of the cooler 50. The diameter of the through hole 23 is a length that can ensure a non-contact state with the screw receiving portion 52 even if manufacturing variations and assembly variations occur.

The printed circuit board 20 is equipped with multiple electronic components. The electronic components provides the circuit, together with the conductor of the printed circuit board 20. The electronic components are soldered to the corresponding lands. The electronic components include electronic components 30 and 40. The electronic component 30 is mounted on the first surface 21 of the printed circuit board 20 that faces the cooler 50. The electronic component 30 is a heat generating component that interposes the TIM 60 with the cooler 50. The heat generating component is an electronic component that generates a large amount of heat, among the multiple electronic components mounted on the printed circuit board 20. The electronic component 30 is disposed at a position that does not overlap with the through hole 23 in the plan view.

The electronic component 30 is a surface-mount type electronic component, for example, a non-leaded package such as BGA, QFN, or SON. BGA is an abbreviation for Ball Grid Array. QFN is an abbreviation for Quad Flat Non-leaded package. SON is an abbreviation for Small Outline Non-leaded package. As an example, the electronic component 30 of the present embodiment is a BGA type electronic component. The BGA type electronic component may be provided with a lid for heat dissipation, or may not be provided with the lid.

The electronic component 30 includes a semiconductor chip 31, a redistribution substrate 32, a lid 33, a solder 34, and a sealing resin body 35. The semiconductor chip 31 is also referred to as an IC chip. The semiconductor chip 31 is, for example, a SoC. SoC is an abbreviation for System on a Chip. The redistribution substrate 32 is also referred to as an interposer. The redistribution substrate 32 is formed by arranging redistribution wirings on an insulating base material. The redistribution wirings are electrically connected to the terminals of the semiconductor chip 31. The redistribution substrate 32 has a generally rectangular shape in the plan view. The semiconductor chip 31 is disposed in a central region of the redistribution substrate 32.

The lid 33 will be also referred to as a lid member, a cover, a heat dissipation member, or the like. The lid 33 is formed using a metal material having excellent thermal conductivity, such as Cu. The lid 33 is interposed between an upper surface of the semiconductor chip 31 and the cooler 50 in the Z direction. The lid 33, together with the TIM 60, transfers heat generated from the semiconductor chip 31 to the cooler 50.

The lid 33 is disposed on a mounting surface side of the redistribution substrate 32 on which the semiconductor chip 31 is mounted. The lid 33 is disposed so as to overlap with at least a part of the semiconductor chip 31 in the plan view, for example. The lid 33 is preferably disposed so as to enclose the semiconductor chip 31. The lid 33 covers the semiconductor chip 31. The lid 33 is soldered to the redistribution substrate 32.

The solder 34 has a ball shape. The solder 34 will be also referred to as a solder ball. The solder 34 is disposed on a surface of the redistribution substrate 32 opposite to the mounting surface on which the semiconductor chip 31 is mounted. The solder 34 is electrically connected to the redistribution wiring. Multiple solders 34 are arranged in a matrix. The solders 34 are joined to lands (not shown) provided on the first surface 21 of the printed circuit board 20.

The electronic component 40 is mounted on the second surface 22 of the printed circuit board 20. The electronic component 40 is disposed at a position overlapping with the electronic component 30 in the plan view. The electronic component 40 is a component that aims to stabilize an operation of the electronic component 30. In the present embodiment, as an example, the electronic component 40 is a bypass capacitor. For example, the bypass capacitor suppresses fluctuations in the power supply voltage supplied to the electronic component 30. For example, the bypass capacitor suppresses the inflow of noise to the electronic component 30 and/or the outflow of noise from the electronic component 30. Multiple electronic components 40 are mounted on the second surface 22. The multiple electronic components 40 are disposed within a region surrounded by a frame-shaped main body portion 71.

The cooler 50 cools at least a part of the multiple electronic components mounted on the printed circuit board 20. The cooler 50 cools a heat generating component including the electronic component 30. The cooling method of the cooler 50 is not particularly limited. The electronic device 10 may have a housing separate from the cooler 50, or the cooler 50 may form a part of a housing. A part of the housing may serve as the cooler 50.

As an example, the cooler 50 of the present embodiment is of a water-cooling type. The cooler 50 forms a part of a housing (case) that houses the printed circuit board 20 and the electronic components 30 and 40. For convenience, only a part of the housing is shown in FIG. 1. The cooler 50 is made of a metal material such as aluminum. The cooler 50 has a cooler main body 51 and a screw receiving portion 52.

The cooler main body 51 is disposed to face the first surface 21 of the printed circuit board 20. The cooler main body 51 has a flow passage 511 formed therein. The flow passage 511 is disposed so as to overlap with at least the heat generating component in the plan view so that the heat generating component is effectively cooled. The flow passage 511 extends in a predetermined direction perpendicular to the Z direction.

An inlet pipe and an outlet pipe (not shown) are connected to the flow passage 511. A refrigerant 512 introduced from the inlet pipe flows through the flow passage 511 and is discharged from the outlet pipe. Examples of the refrigerant 512 include a phase transition refrigerant such as water or ammonia, and a phase non-transition refrigerant such as ethylene glycol. The cooler main body 51 may have fins that protrude into the flow passage 511. When the cooler main body 51 has the fins, the contact area with the refrigerant 512 increases, so that heat exchange performance with the refrigerant 512, that is, cooling efficiency increases.

The screw receiving portion 52 connects to the cooler main body 51. The screw receiving portion 52 protrudes from the cooler main body 51 towards the printed circuit board 20. The screw receiving portion 52 may integrally connect to the cooler main body 51 by using the same material as the cooler main body 51. The screw receiving portion 52 may be, for example, a part of a molded body. The screw receiving portion 52 may be connected to the cooler main body 51 by, for example, joining. The screw receiving portion 52 extends in the Z direction.

The cooler 50 has a screw hole 53 that opens at the protruding tip of the screw receiving portion 52. The screw hole 53 is provided to correspond to the screw 80 for fixing the back plate 70 to the cooler 50. The screw 80 is screwed into the screw hole 53. The screw 80 will be also referred to as a fixing screw. The cooler 50 has the screw receiving portions 52 with the number corresponding to the number of the leg portions 72 of the back plate 70.

As an example, the cooler 50 of the present embodiment has four screw receiving portions 52. The screw receiving portion 52 passes through the through hole 23 of the printed circuit board 20 and protrudes from the second surface 22. The screw receiving portion 52 is not in contact with a wall surface of the printed circuit board 20, the wall surface defining the through hole 23.

The TIM 60 is a heat-conducting member such as a heat-dissipating gel or a heat-conducting sheet. The TIM is an abbreviation for Thermal Interface Material. The TIM 60 is interposed between the electronic component 30 and the cooler 50. The TIM 60 is provided at a position overlapping with the electronic component 30, particularly, the semiconductor chip 31 in the plan view. The TIM 60 thermally connects the electronic component 30 and the cooler 50.

As an example, the TIM 60 of the present embodiment includes TIM 61 and TIM 62. The TIM 61 is interposed between the top surface of the semiconductor chip 31 and the lid 33 to thermally connect the semiconductor chip 31 and the lid 33. The TIM 62 is interposed between the lid 33 and the cooler 50 (cooler main body 51) to thermally connect the lid 33 and the cooler 50. The TIM 62 is provided so as to enclose the TIM 61 in the plan view.

The back plate 70 presses the printed circuit board 20 against the cooler main body 51 of the cooler 50. The back plate 70 presses the electronic component 30 against the cooler 50. The back plate 70 has a spring property, and presses the printed circuit board 20 against the cooler 50 by a reaction force generated by deformation of the spring. The back plate 70 is disposed on the second surface 22 side of the printed circuit board 20.

The back plate 70 has the main body portion 71 and multiple leg portions 72. The main body portion 71 is disposed so as to overlap with at least a part of the electronic component 30 in the plan view. The main body portion 71 is disposed in contact with the back surface 22 in a state where the back plate 70 is fixed to the cooler 50. The leg portions 72 connect to the main body portion 71. In the state where the back plate 70 is fixed to the cooler 50, at least a part of the leg portion 72 is disposed to be spaced apart from the second surface 22. For stable fixation, it is preferable that the number of leg portions 72 is three or more.

As an example, the main body portion 71 of the present embodiment has a frame shape. The main body portion 71 has a generally rectangular loop shape in the plan view. The main body portion 71 is disposed so as to overlap with an outer peripheral region of the redistribution substrate 32 in the plan view. The main body portion 71 is disposed so as to surround the semiconductor chip 31 in the plan view. The leg portions 72 extend from the four corners of the main body portion 71. The back plate 70 has the four leg portions 72. The back plate 70 has bent portions at boundaries between the main body portion 71 and the leg portions 72 and at intermediate positions of the leg portions 72. The leg portions 72 are provided so as to be spring deformable in the Z direction. The leg portions 72 are spaced apart from the second surface 22 over substantially their entire length.

The leg portion 72 is provided with a hole 73 at an end thereof for fixing the screw 80 to the screw receiving portion 52. The hole 73 of the leg portion 72 will be also referred to as a leg hole 73. A distance between the ends of two adjacent leg portions 72 along the outer periphery of the redistribution substrate 32 is greater than a distance between the ends connecting to the main body portion 71. The leg portions 72 extend obliquely from the main body portion 71. In a state where the screws 80 are fastened, the spring reaction force of the leg portions 72 causes the main body portion 71 to be pressed against the printed circuit board 20, and therefore the electronic component 30 is pressed against the cooler 50. In the example shown in FIG. 1, the leg portions 72 are not in contact with the screw receiving portions 52 in the state where the screw 80 are fastened. Alternatively, the leg portions 72 may be configured to be in contact with the protruding tip surfaces of the screw receiving portions 52.

A fixing part 90 for connecting the leg portion 72 and the cooler 50 passes through the through hole 23 of the printed circuit board 20. The fixing part 90 is not in contact with the printed circuit board 20. As an example, the fixing part 90 of the present embodiment includes the screw 80 and the screw receiving portion 52. The screw 80 passes through the hole 73 of the leg portion 72 and is screwed with the corresponding screw hole 53.

### <Summary of First Embodiment>

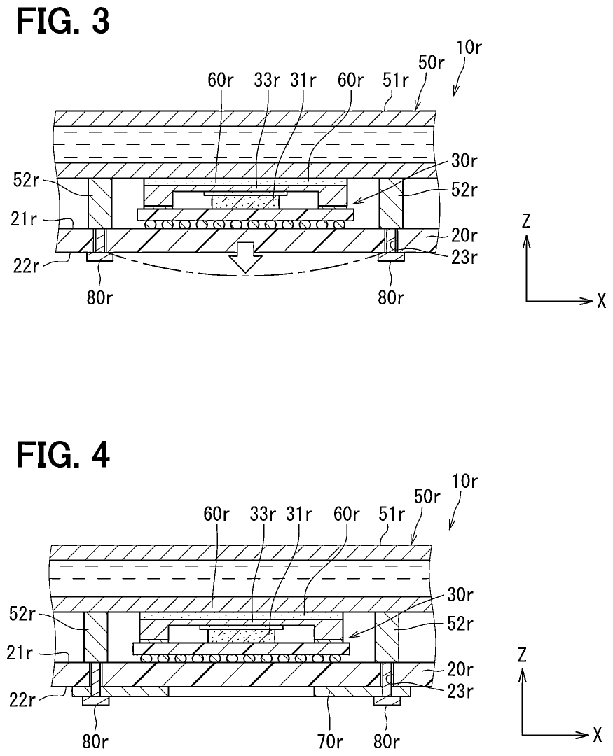

FIGS. 3 and 4 are cross-sectional views showing reference examples. In the reference examples, a character “r” is added to the end of the reference numeral of an element related to the present embodiment. FIGS. 3 and 4 correspond to FIG. 1. In FIGS. 3 and 4, illustrations of components equivalent to the electronic components 40 are omitted.

An electronic device 10r shown in FIG. 3 does not include a back plate. A cooler 50r has support portions 52r extending from a cooler main body 51r toward a printed circuit board 20r. The support portion 52r supports the printed circuit board 20r. The support portion 52r is formed with a screw hole (not shown) formed therein. A screw 80r passes through a through hole 23r of the printed circuit board 20r and screwed into the screw hole. The head of the screw 80r and the support portion 52r hold the printed circuit board 20r therebetween.

In the configuration shown in FIG. 3, the printed circuit board 20r is pressed against the cooler 50r by the screws 80r. Since the printed circuit board 20r is pressed against the cooler 50r at positions outside the electronic component 30r in the plan view, it is difficult to sufficiently compress TIMs 60r. In other words, the thermal resistance cannot be reduced. Furthermore, the printed circuit board 20r is warped as indicated by the dashed line.

An electronic device 10r shown in FIG. 4 includes a back plate 70r. The back plate 70r has a frame-shaped main body portion and four leg portions. The leg portions extend from the main body portion, and is coplanar with the main body portion. The screw 80r passes through a hole provided in the leg portion and the through hole 23r, and is screwed into a screw hole of the support portion 52r. The head of the screw 80r and the support portion 52r hold the back plate 70 and the printed circuit board 20r therebetween.

In the configuration shown in FIG. 4, the back plate 70r is disposed at a position overlapping with an electronic component 30r in the plan view. Therefore, it is possible to compress the TIMs 60r, so the thermal resistance can be reduced. The back plate 70r can suppress bending of the printed circuit board 20r. However, since the head of the screw 80r holds the printed circuit board 20r with the support portion 52r via the leg portion of the back plate 70r, the fastening of the screw causes distortion in the printed circuit board 20r. In other words, stress caused by screw fastening acts on the solder joined portions of the electronic component 30r, degrading the connection reliability.

According to the electronic device 10 of the present embodiment, the main body portion 71 of the back plate 70 is in contact with the second surface 22 of the printed circuit board 20 at a position overlapping with at least a part of the electronic component 30. Therefore, it is possible to compress the TIMs 60 (thermal conductive material) by the load of the back plate 70, thereby reducing the thermal resistance. In addition, the leg portions 72 of the back plate 70 are spaced apart from the second surface 22, and the fixing parts 90 pass through the through holes 23 and are not in contact with the printed circuit board 20. As a result, the stress caused by fixing the leg portions 72 of the back plate 70 to the cooler 50 does not act on the solder joined portions (mounting portions) of the electronic components 30. Therefore, it is possible to suppress the degradation of the connection reliability while reducing the thermal resistance.

As illustrated, the fixing part 90 may include the screw 80 and the screw receiving portion 52. The screw receiving portion 52 protrudes from the cooler main body 51 toward the printed circuit board 20 and has the screw hole 53 into which the screw 80 is screwed. The screw 80 passes through the hole 73 provided in the leg portion 72 and screwed with the screw hole 53. The fixing part 90 fixes the back plate 70 to the cooler 50 without contacting the printed circuit board 20. Therefore, it is possible to reduce the thermal resistance and to suppress the stress caused by the screw fastening from acting on the solder joined portions of the electronic component 30.

As illustrated in the example, the screw receiving portion 52 may be configured to pass through the through hole 23 and protrude on the second surface 22 side. The screw receiving portion 52 passes through the through hole 23 in a state without contacting the printed circuit board 20. Therefore, it is possible to reduce the thermal resistance and suppress the degradation of the connection reliability. Furthermore, since the screw receiving portion 52 protrudes on the second surface 22 side, the length of the screw 80 can be shortened, and fastening can be stabilized.

As illustrated in the example, the main body portion 71 may have a frame shape so as to overlap with the outer peripheral region of the electronic component 30 in the plan view. In such a case, it is possible to compress the TIMs 60 with a small load while suppressing deformation (bending) of the printed circuit board 20. The bypass capacitor may be mounted as the electronic component 40 within the area surrounded by the frame-shaped main body portion 71 on the second surface 22. By employing the frame-shaped main body portion 71 and intentionally providing the area that allows elements to be mounted, it is possible to mount electronic component 40 (bypass capacitor) near the electronic component 30. For example, fluctuations in the power supply voltage supplied to the electronic component 30 can be suppressed. For example, the inflow of noise to the electronic component 30 and/or the outflow of noise from the electronic component 30 can be suppressed.

As illustrated, the electronic component 30 may be a BGA type electronic component equipped with the lid 33 for heat dissipation. According to the configuration described above, it is possible to compress the TIM 61 interposed between the semiconductor chip 31 and the lid 33 and the TIM 62 interposed between the lid 33 and the cooler 50.

### <Modification>

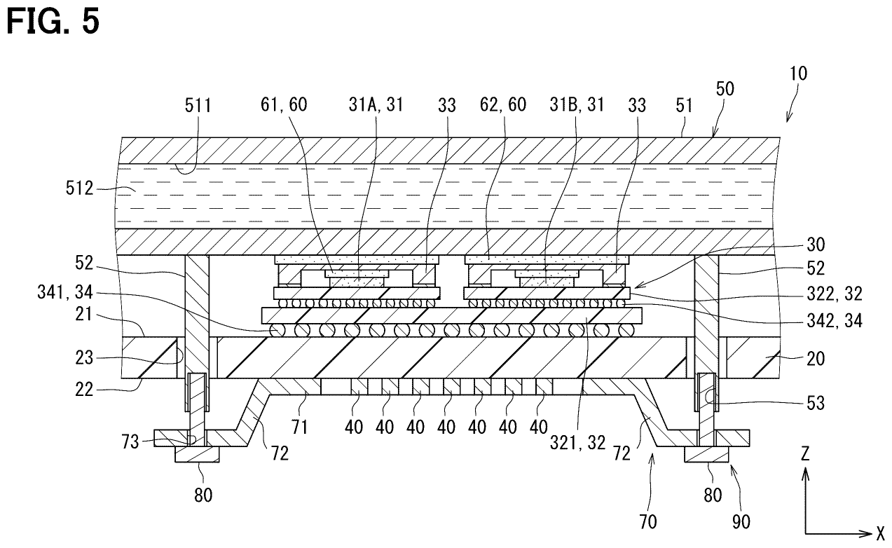

Although an example in which the electronic component 30 has a single (one) semiconductor chip 31 has been shown, the present disclosure is not limited to such an example. The electronic component 30 may include multiple semiconductor chips. For example, as shown in FIG. 5, a multi-chip module may be adopted as the electronic component 30. The electronic component 30 includes multiple semiconductor chips 31. The semiconductor chip 31 includes semiconductor chips 31A and 31B. The redistribution substrate 32 includes a main board 321 and multiple sub boards 322. The solder 34 includes solder 341 provided on a surface of the main board 321 facing the printed board 20 and solder 342 provided on surfaces of the sub boards 322 facing the printed board 20.

A semiconductor chip 31A is mounted on one of the sub boards 322, and a semiconductor chip 31B is mounted on the other of the sub boards 322. The sub boards 322 are mounted on the main board 321. A lid 33 is mounted on each of the sub boards 322 so as to cover the corresponding semiconductor chip 31A or 31B. The TIM 61 is disposed between the semiconductor chip 31A and the lid 33. Also the TIM 61 is disposed between the semiconductor chip 31B and the lid 33. The TIM 62 is disposed between the lid 33 of the semiconductor chip 31A and the cooler 50. Also, the TIM 62 is disposed between the lid 33 of the semiconductor chip 31B and the cooler 50.

In the example of FIG. 5, two BGA-type electronic components each having the lid 33 are mounted on the main board 321. However, the present disclosure is not limited to this example. The number of the BGA-type electronic component(s) with the lid(s) 33 mounted on the main board 321 may be one, or may be three or more. The electronic component 30 may include the BGA-type electronic component with the lid 33 as well as an electronic component of another structure.

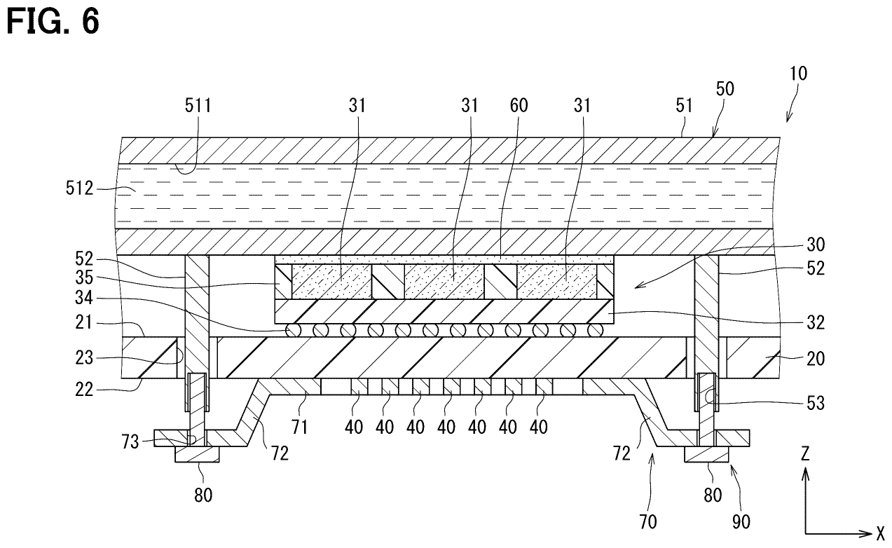

As shown in FIG. 6, a chiplet may be employed as the electronic component 30. The electronic component 30 includes multiple semiconductor chips 31. The multiple semiconductor chips 31 are mounted on a common (single) redistribution substrate 32. The semiconductor chips 31 are sealed with a sealing resin body 35. The TIM 60 is interposed between the top surface of the electronic component 30 and the cooler 50 to thermally connect the top surface of the electronic component 30 and the cooler 50.

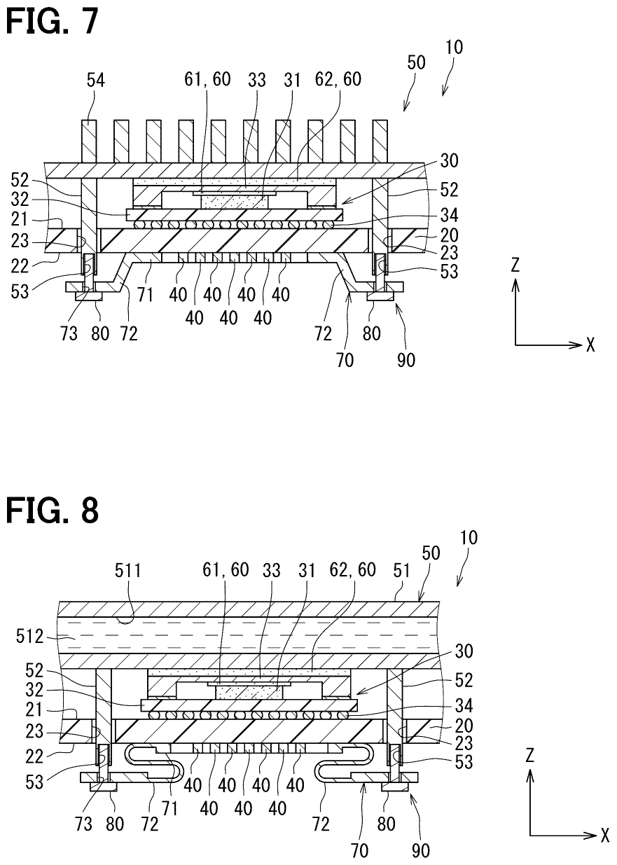

The structure of the cooler 50 is not limited to the example shown in FIG. 1. For example, as shown in FIG. 7, a heat sink may be used as the cooler main body 51. The heat sink will be also referred to as a heat sink or a cooling plate. As shown in FIG. 7, the cooler 50 may have a number of fins 54. The fins 54 are connected to the surface of the cooler main body 51 opposite to the contact surface of the TIM 60.

The structure of the leg portion 72 is not limited to the example shown in FIG. 1. The leg portion 72 may have any structure as long as it is spring deformable in the Z direction. For example, as shown in FIG. 8, the leg portion 72 may have a generally S-shaped leaf spring structure. The leg portion 72 has a folded structure extending in the Z direction. Additionally, the leg portion 72 may be spaced apart from the second surface 22 along their entire length. The base portion of the leg portion 72 that connects to the main body portion 71 may be in contact with the second surface 22, and the portion further from the base portion may be spaced apart from the second surface 22.

### Second Embodiment

The present embodiment is a modification based on the preceding embodiment, and the description of the preceding embodiment can be incorporated. In the preceding embodiment, the main body portion 71 of the back plate 70 has the frame shape. Alternatively, the main body portion 71 may have a shape other than the frame shape.

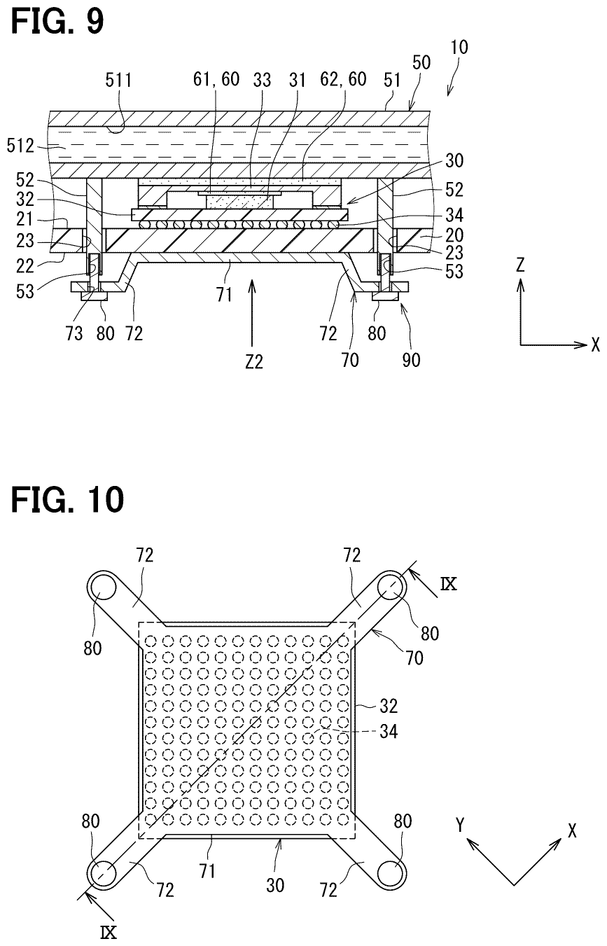

FIG. 9 is a cross-sectional view showing an example of an electronic device according to the second embodiment. FIG. 9 corresponds to FIG. 1. FIG. 9 is a cross-sectional view taken along a line IX-IX in FIG. 10. FIG. 10 is a plan view when viewed along a Z2 direction in FIG. 9. FIG. 10 corresponds to FIG. 2. FIG. 10 shows the shapes of the electronic component and the back plate, and the positional relationship between the electronic component and the back plate.

As shown in FIGS. 9 and 10, a back plate 70 has a main body portion 71 and leg portions 72. The main body portion 71 is solid in the plan view. The main body portion 71 is provided so as to enclose the entire area in which the solders 34 are arranged. The main body portion 71 may be provided so as to overlap with most of the electronic component 30 in the plan view, or may be provided so as to enclose the entire electronic component 30.

As an example, the main body portion 71 of the present embodiment has a generally rectangular shape in the plan view. The main body portion 71 encompasses the entire area of the redistribution substrate 32 where the solders 34 are disposed. The main body portion 71 is provided so as to overlap with most of the electronic component 30 in the plan view. The leg portions 72 connect to the four corners of the main body portion 71. Other configurations are similar to those described in the preceding embodiment.

### <Summary of Second Embodiment>

As illustrated, the main body portion 71 may be provided so as to enclose the entire arrangement area of the solders 34 in the plan view. The main body portion 71 may be provided so as to overlap with most of the electronic component 30. Similar to the configuration illustrated in the preceding embodiment, it is possible to reduce the thermal resistance and to suppress the degradation of connection reliability. In particular, it is possible to effectively compress the TIM 60 while suppressing unevenness of the load applied to the TIM 60 within the plane, that is, in the planar direction.

### Third Embodiment

The present embodiment is a modification based on the preceding embodiment, and the description of the preceding embodiment can be incorporated. In the preceding embodiment, the screw receiving portion 52 passes through the through hole 23 and protrudes on the second surface 22 side. Alternatively, the screw receiving portion 52 may not be inserted into the through hole 23.

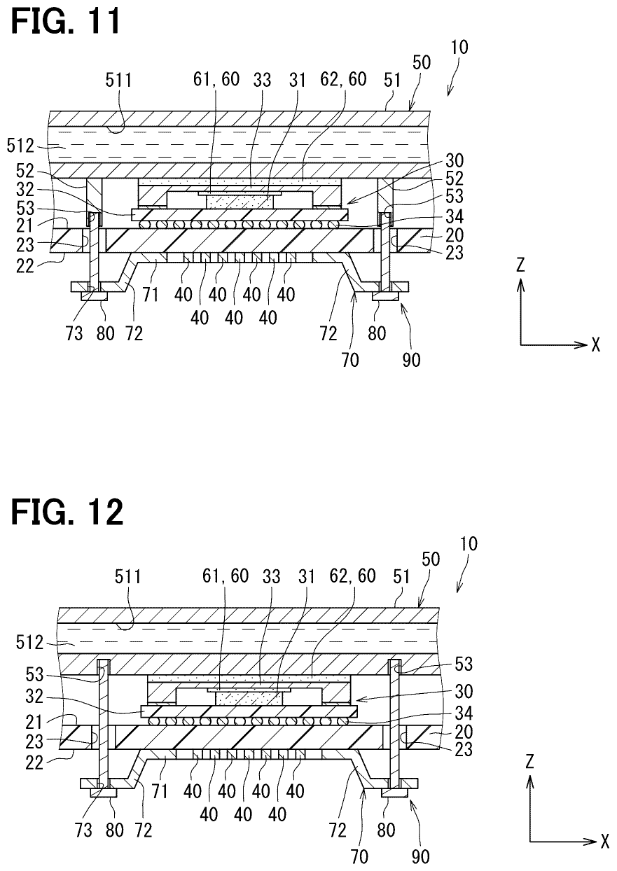

FIG. 11 is a cross-sectional view illustrating an example of an electronic device according to the third embodiment. FIG. 11 corresponds to FIG. 1. As shown in FIG. 11, the cooler 50 has a cooler main body 51 and screw receiving portions 52. The screw receiving portion 52 extends in the Z direction from the cooler main body 51. The protruding tip of the screw receiving portion 52 is located above the first surface 21, that is, on the cooler main body 51 side, in a state in which the back plate 70 is fixed to the cooler 50. The screw receiving portion 52 is not inserted into the through hole 23.

The screw 80 passes through a hole 73 that is located at a position spaced from the second surface 22. The screw 80 passes through the through hole 23 without contacting the wall surface of the through hole 23. The diameter of the through hole 23 is larger than the outer diameter of the screw 80. The diameter of the through hole 23 is a length that can ensure a non-contact state with the screw 80 even if manufacturing variations and assembly variations occur. The screw 80 passes through the hole 73 and the through hole 23 and protrudes on the first surface 21 side. The screw 80 is screwed into the screw hole 53 of the screw receiving portion 52 disposed on the first surface 21 side. Other configurations are similar to those described in the preceding embodiment.

### <Summary of Third Embodiment>

As illustrated, it may be configured so that the screw receiving portion 52 does not pass through the through hole 23, and the screw 80 passes through the through hole 23 and protrudes on the first surface 21 side. Similar to the configuration illustrated in the preceding embodiment, it is possible to reduce the thermal resistance and to suppress the degradation of connection reliability. In particular, it is possible to reduce the protruding height of the screw receiving portion 52 relative to the cooler main body 51. Therefore, in a configuration in which the cooler main body 51 and the screw receiving portion 52 are molded integrally, for example, the structure of a molding die can be simplified. In addition, the manufacturing costs can be reduced. In the configuration shown in FIG. 11, the back plate 70 having the structure illustrated in the second embodiment may be used.

### Fourth Embodiment

The present embodiment is a modification based on the preceding embodiment, and the description of the preceding embodiment can be incorporated. In the preceding embodiment, the cooler 50 have the screw receiving portion 52. Alternatively, a configuration without having the screw receiving portion 52 may be adopted.

FIG. 12 is a cross-sectional view showing an example of an electronic device according to the fourth embodiment. FIG. 12 corresponds to FIG. 1. As shown in FIG. 12, the cooler 50 has a cooler main body 51. The cooler 50 does not have a screw receiving portion 52. The cooler main body 51 is formed with a screw hole 53 that opens on the surface facing the printed circuit board 20.

The screw 80 passes through a hole 73 located at a position spaced apart from the second surface 22. The screw 80 passes through the through hole 23 without contacting the wall surface of the through hole 23. The diameter of the through hole 23 is larger than the outer diameter of the screw 80. The diameter of the through hole 23 is a length that can ensure a non-contact state with the screw 80 even if manufacturing variations and assembly variations occur. The screw 80 passes through the hole 73 and the through hole 23 and protrudes on the first surface 21 side. The screw 80 is screwed into the screw hole 53 of the cooler main body 51. Other configurations are similar to those described in the preceding embodiment.

### <Summary of Fourth Embodiment>

As illustrated, the screw 80 may pass through the hole 73 of the leg portion 72 and the through hole 23 of the printed circuit board 20 and is screwed into the screw hole 53 of the cooler main body 51. Similar to the configuration illustrated in the preceding embodiment, it is possible to reduce the thermal resistance and to suppress the degradation of connection reliability. In particular, since the screw receiving portion 52 can be eliminated, the configuration of the cooler 50 can be simplified. For example, manufacturing costs can be reduced. In the configuration shown in FIG. 12, the back plate 70 having the structure illustrated in the second embodiment may be used.

### Fifth Embodiment

The present embodiment is a modification based on the preceding embodiment, and the description of the preceding embodiment can be incorporated. In the preceding embodiment, the back plate 70 is fixed to the cooler 50 by the screw fastening. Alternatively, fixing means other than the screw fastening may be used.

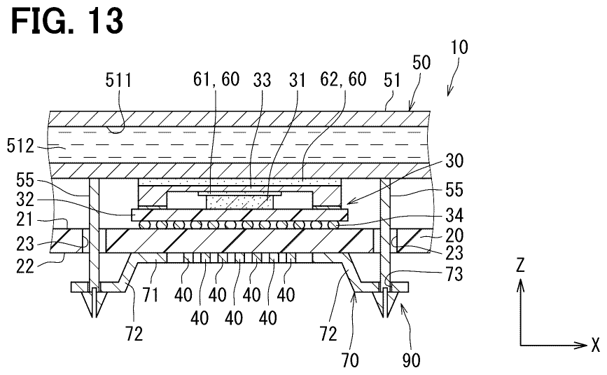

FIG. 13 is a cross-sectional view showing an example of an electronic device according to the fifth embodiment. FIG. 13 corresponds to FIG. 1. As shown in FIG. 13, a cooler 50 has a cooler main body 51 and protrusions 55. The protrusion 55 connects to the cooler main body 51 and protrudes from the cooler main body 51 towards the printed circuit board 20. The protrusion 55 may be integrally connected to the cooler main body 51 by using the same material. The protrusion 55 may be, for example, a part of a molded body. The protrusion 55 may be connected to the cooler main body 51 by, for example, joining. The protrusion 55 extends in the Z direction.

The protrusion 55 passes through the through hole 23 and protrudes on the second surface 22 side. The diameter of the through hole 23 is larger than the outer diameter of the protrusion 55. The diameter of the through hole 23 is a length that can ensure a non-contact state with the protrusion 55 even if manufacturing variations and assembly variations occur. The protrusion 55 is engaged with the back plate 70 while passing through the hole 73 in the leg portion 72. The protruding tip of the protrusion 55 is engaged with the periphery of the hole 73 by a snap-fit structure, a crimping structure, or the like. The fixing part 90 includes the protrusion 55. Other configurations are similar to those described in the preceding embodiment.

### <Summary of Fifth Embodiment>

As illustrated, the cooler 50 may be provided with the protrusion 55 that protrudes from the cooler main body 51 toward the printed circuit board 20 and engages with the back plate 70 in a state of passing through the hole 73. The fixing part 90 may be configured to include the protrusion 55. Similar to the configuration illustrated in the preceding embodiment, it is possible to reduce the thermal resistance and to suppress the deterioration of connection reliability. In particular, since the screw 80, which is a separate member, can be eliminated, the number of parts can be reduced. In the configuration shown in FIG. 13, the back plate 70 having the structure shown in the second embodiment may be used.

### Other Embodiments

The present disclosure in the specification, the drawings and the like is not limited to the embodiments illustrated hereinabove. The disclosure encompasses the illustrated embodiments and modifications by those skilled in the art based thereon. For example, the disclosure is not limited to the combinations of components and/or elements illustrated in the embodiments. The disclosure may be implemented in various combinations. The disclosure may have additional parts that may be added to the embodiments. The disclosure encompasses modifications in which components and/or elements are omitted from the embodiments. The disclosure encompasses the replacement or combination of components and/or elements between one embodiment and another. The technical scopes disclosed in the disclosure are not limited to the description of the embodiments. Some of the disclosed technical scopes are indicated by the description of the scope of claims, and should be further understood to include meanings equivalent to the description of the scope of claims and all modifications within the scope.

The disclosure in the specification, the drawings, and the like is not limited by the description of the scope of claims. The disclosure in the specification, the drawings, and the like encompasses the technical ideas described in the claims, and further extends to a wider variety of technical ideas than those in the claims. Thus, various technical ideas can be extracted from the disclosure of the specification, the drawings, and the like without being restricted by the description of the scope of claims.

When an element or a layer is described as “disposed above”, “coupled to” “connected to” or “combined with”, the element or the layer may be directly disposed above, coupled to, connected to, or combined with another element or another layer, or an intervening element or an intervening layer may be present therebetween. In contrast, when an element is described as “directly disposed on,” “directly coupled to,” “directly connected to”, or “directly combined with” another element or another layer, there are no intervening elements or layers present. Other terms used to describe the relationships between elements (for example, “between” vs. “directly between”, and “adjacent” vs. “directly adjacent”) should be interpreted similarly. As used herein, the term “and/or” includes any combination and all combinations relating to one or more of the related listed items. For example, the term A and/or B includes only A, only B, or both A and B. That is, the term A and/or B means at least one of A or B.

Spatial relative terms “inside”, “outside”, “rear”, “bottom”, “low”, “top”, “high”, and the like are used herein to facilitate the description that describes relationships between one element or feature and another element or feature. Spatial relative terms can be intended to include different orientations of a device in use or operation, in addition to the orientations illustrated in the drawings. For example, when the device in the drawing is turned over, an element described as “below” or “immediately below” another element or feature is oriented “above” the other element or feature. Therefore, the term “below” can include both above and below. The device may be oriented in another direction (rotated 90 degrees or in any other direction) and the spatially relative terms used herein are interpreted accordingly.

What is claimed is:

1. An electronic device comprising:
a printed circuit board having a first surface and a second surface opposite to the first surface in a thickness direction, the printed circuit board being formed with a through hole defining openings on the first surface and the second surface;
an electronic component disposed on the first surface of the printed circuit board at a position without overlapping with the through hole in a plan view when viewed in the thickness direction;
a cooler disposed to face the first surface of the printed circuit board;
a heat conductive member interposed between the electronic component and the cooler and thermally connecting the electronic component and the cooler; and
a back plate disposed on the second surface of the printed circuit board and fixed to the cooler via the through hole, wherein
the back plate has a main body portion and a plurality of leg portions,
the main body portion is disposed so as to overlap with at least a part of the electronic component in the plan view and in contact with the second surface of the printed circuit board,
the plurality of leg portions extends from the main body portion and is spaced apart from the second surface of the printed circuit board, and
a fixing part for fixing at least one of the plurality of leg portions of the back plate and the cooler passes through the through hole and is not in contact with the printed circuit board.

2. The electronic device according to claim 1, wherein
each of the plurality of leg portions is formed with a leg hole through which a fixing screw passes,
the cooler has a cooler main body and a screw receiving portion protruding from the cooler main body toward the printed circuit board,
the screw receiving portion is formed with a screw hole into which the fixing screw is screwed, and
the fixing part includes the fixing screw and the screw receiving portion.

3. The electronic device according to claim 2, wherein
the screw receiving portion passes through the through hole of the printed circuit board and protrudes from the second surface of the printed circuit board.

4. The electronic device according to claim 2, wherein
the screw receiving portion protrudes from the cooler main body without reaching the through hole of the printed circuit board, and
the fixing screw passes through the through hole of the printed circuit board and protrudes from the first surface of the printed circuit board.

5. The electronic device according to claim 1, wherein
each of the plurality of leg portions is formed with a leg hole through which a fixing screw passes,
the cooler is formed with a screw hole into which the fixing screw is screwed, and
the fixing part includes the fixing screw and the screw hole.

6. The electronic device according to claim 1, wherein
each of the plurality of leg portions is formed with a leg hole,
the cooler has a cooler main body and a protrusion that protrudes from the cooler main body toward the printed circuit board and engages with the back plate while passing through the through hole of the printed circuit board, and
the fixing part includes the protrusion.

7. The electronic device according to claim 1, wherein
the main body portion of the back plate has a frame shape that overlaps with an outer periphery of the electronic component in the plan view.

8. The electronic device according to claim 7, further comprising:
a bypass capacitor mounted on the second surface of the printed circuit board for the electronic component in an area surrounded by the frame shape of the main body portion.

9. The electronic device according to claim 1, wherein
the main body portion encloses an entire solder placement area of the electronic component on which solder is placed in the plan view.

10. The electronic device according to claim 1, wherein
the electronic component is a ball grid array (BGA) electronic component having a heat dissipation lid.

11. The electronic device according to claim 1, wherein
the electronic component includes a plurality of semiconductor chips.
